(19) United States
(12) Patent Application Publication
(10) Pub. No.: US 2025/0103487 A1
(43) Pub. Date: Mar. 27, 2025

(54) NOR MEMORY AND READING METHOD THEREOF

(71) Applicant: GIGADEVICE SEMICONDUCTOR INC., Beijing (CN)

(72) Inventors: Ruwei SU, Beijing (CN); Hong HU, Beijing (CN); Sai ZHANG, Beijing (CN)

(21) Appl. No.: 18/894,101

(22) Filed: Sep. 24, 2024

(30) Foreign Application Priority Data
Sep. 25, 2023 (CN) 202311246228.4

(51) Int. Cl. G06F 12/02

(52) U.S. Cl. CPC G06F 12/0246

(57) ABSTRACT

Disclosed is a NOR memory and reading method thereof. The method for reading a NOR memory comprises: consecutively receiving at least two random access addresses in a random read mode; and consecutively outputting data read according to the received access addresses. The method can improve the speed when reading data from multiple random addresses in the NOR memory.

### CROSS-REFERENCE TO RELATED APPLICATIONS

This application claims priority to Chinese patent application No. 202311246228.4 filed on Sep. 25, 2023, the disclosure of which is incorporated herein by reference in its entirety and for all purposes.

### TECHNICAL FIELD

The disclosure herein relates to the field of storage, and in particular, to a NOR memory and a reading method thereof.

### BACKGROUND

Currently, flash memory is widely used in various electronic devices, with NOR flash memory being used in an increasing number of devices.

Therefore, it is desirable to improve the data transmission speed of the NOR flash memory.

### SUMMARY

According to an embodiment of the present disclosure, a method for reading a NOR memory is provided, comprising: consecutively receiving at least two random access addresses in a random read mode; and consecutively outputting data read according to the received access addresses.

According to an embodiment of the present disclosure, a NOR memory is provided, comprising: one or more NOR memory arrays fabricated on one or more dies; an access interface for communicating information with the outside of the NOR memory; and a control module configured to control a read operation to the NOR memory arrays according to information received from the access interface, so as to implement the method according to the previously described embodiment of the present disclosure.

### BRIEF DESCRIPTION OF FIGURES

The above and other objects, features and advantages of the present disclosure will become more apparent from the more detailed description of the exemplary embodiments of the present disclosure taken in conjunction with the accompanying drawings, wherein the same reference numerals generally refer to the same parts in exemplary embodiments of the present disclosure.

FIG. 1 illustrates an exemplary composition diagram of a NOR memory according to an embodiment of the present disclosure.

FIG. 2 illustrates an exemplary timing diagram of a random read mode according to an embodiment of the present disclosure.

### DETAILED DESCRIPTION

Some embodiments of the present disclosure will be described in more detail below with reference to the accompanying drawings. Although the embodiments of the present disclosure are shown in the drawings, it should be understood that the present disclosure may be embodied in various forms and should not be limited to the embodiments set forth herein. Rather, these embodiments are provided so that this disclosure will be thorough and complete, and will fully convey the scope of the disclosure to those skilled in the art.

At present, the continuous transmission speed of NOR memory is very fast, that is, the speed of continuously reading data starting from one address is very fast. However, it is found that for situations where multiple random addresses need to be read, currently the random read speed is limited by the transmission process of read commands. For example, the transmission format for the existing conventional read command is: cmd+address+dummy clk+data, where “cmd” represents the command sent by the host to the memory (for example, the cmd may be a read command value), “address” represents the access address sent by the host to the memory, “dummy clk” represents several dummy clock cycles (i.e. idle waiting time), and “data” represents the data read out in response to the received access address and sent by the memory to the host. That is to say, the entire transmission process for the existing read command is: the host consecutively sends the read command value (“cmd”) and the access address (“address”) to the memory, and then after a certain idle waiting time (“dummy clk”), the memory sends data (“data”) read from the received access address to the host. Therefore, when the host consecutively reads data from multiple random addresses using the existing read command, it needs to send the read command multiple times, and each read command includes the read command value sent at the beginning and the idle waiting time between the address and the read data. For example, in the case where the host wants to read in bursts N bytes from address A and then read in bursts M bytes from address B, it needs to perform two complete transmission processes including above read commands. In this disclosure, the so-called “random” address or access address means an address that can be arbitrarily specified by the user (in some scenarios, multiple random addresses may be continuous addresses).

In addition, the related technology also proposes another read command for the case of continuously performing multiple random address read operations. The continuous read command may initiate a series of (multiple) read commands of the same type through one command value, that is, only one command value need to be transmitted during the first read operation, eliminating the transmission of command values at the beginning of subsequent read commands. That is to say, the transmission format of subsequent read commands may be changed to: address+dummy clk+data. However, like the conventional read command mentioned above, a read operation can be performed only if the previous transmission process is completed, that is, the process of a read operation is performed after the output of data of the previous transmission process has been finished.

It may be noted that in all the embodiments of this application, the symbol “+” has no specific meaning, and the symbol “+” does not exist in an actual transmission. The symbol “+” in this disclosure is only used to indicate the connection between its previous and following parts of the read command. For example, in “address+dummy clk+data”, the “address” may be a string of consecutive characters (i.e., one or more characters) representing an address; the “dummy clk” may be a certain time interval or placeholder(s) with a preset length (i.e., any character(s) without specific meaning, also known as a useless character(s)) or left blank in any other way; and the “data” may be a string of (i.e., one or more) consecutive characters (typically binary characters) representing data stored in the address. For example, the “address+dummy clk+data” may be “111100001010”, where the first four characters “1111” represent the “address”, the middle four characters “0000” represent the “dummy clk”, and the last four characters “1010” represent the “data” stored in the address “1111”. In an actual use, there is no need to actually transmit any content regarding the “+” in the transmission format. The following will not repeat this.

The present disclosure believes that the aforementioned existing read command setting affects the read speed of multiple random addresses.

Therefore, the present disclosure proposes a new read mode for NOR memory, which can reduce unnecessary information transmission and idle waiting time in the case of performing consecutive read operations for multiple random addresses, thereby improving the transmission speed of the read data.

In some embodiments, the present disclosure proposes a new random read mode. After the random read mode is initiated, at least two random access addresses may be received consecutively, and then the data read according to the received access addresses is consecutively output. Therefore, in some cases, the time required for transmitting the value corresponding to the read command may be saved. In addition, in some cases, the memory may receive subsequent access addresses during the read latency (the time duration between the start of receiving the first access address and the start of outputting the data stored in first access address) necessary for the first read operation (i.e., the read operation performed for the first received address), thus further saving data transmission time for multiple random read operations compared to related technologies. In addition, in some cases, since the subsequent access addresses are pre-stored, the subsequent read operation does not have to hold until the previous read operation is completely finished, and parts of multiple consecutive read operations may be performed in parallel, like a pipeline. For example, during the transmission of data read from the previous access address, it may start to activate the corresponding word line (WL) and bit line (BL) according to the subsequent access address; therefore, it can reduce the idle waiting time for multiple random read operations and further improve data transmission speed.

As will be elaborated later, in some embodiments, the random read mode of the present disclosure may be initiated by receiving a predetermined command value.

The random read mode may include: a parameter indicating the random read mode is initiated; n random access addresses received consecutively, where n is an integer greater than 1; a dummy clk indicating a number of dummy clock cycles, where the number is a number greater than or equal to 0; and output data read respectively according to the n random access addresses, which are output consecutively in the order of the received access addresses.

That is, the transmission format of the random read mode may be represented as:
cmd+address_1+ . . . +address_n+dummy clk+address_1_data+ . . . +address_n_data,
where, cmd represents the predetermined command value; address_1+ . . . +address_n represent n random access addresses received consecutively, where n is an integer greater than 1; dummy clk represents a predetermined number of dummy clock cycles, where the predetermined number is a number greater than or equal to 0;
address_1_data+ . . . +address_n_data represent data read respectively according to the n random access addresses, which are output consecutively in the order of the received the access addresses.

In some cases, the transmissions in the random read mode may be continuously performed after receiving a read transmission indicating performing the random read mode, and the predetermined command value representing the cmd is omitted in the subsequent transmission format. In some embodiments, two or more continuous read transmissions are performed continuously; the first read transmission includes: a parameter indicating the random read mode is initiated; n random access addresses received consecutively, where n is an integer greater than 1; a dummy clk indicating a number of dummy clock cycles, where the number is a number greater than or equal to 0; and output data read respectively according to the n random access addresses, which are output consecutively in the order of the received access addresses. And the second read transmission includes: n random access addresses received consecutively, where n is an integer greater than 1, a dummy clk indicating a number of dummy clock cycles, where the number is a number greater than or equal to 0; and output data read respectively according to the n random access addresses, which are output consecutively in the order of the received access addresses. That is, the parameter indicating the random read mode is initiated is omitted in the second read transmission (and the following read transmission, if any).

That is, two or more continuous read transmissions are performed continuously; wherein, the transmission format of the first read transmission of the two continuous read transmissions is represented as: cmd+address_1+ . . . +address_n+dummy clk+address_1_data+ . . . +address_n_data, and the transmission format of the second read transmission of the two continuous read transmissions is represented as: address_1+ . . . +address_n+dummy clk+address_1_data+ . . . +address_n_data. Therefore, after the read transmission is initiated by using the command cmd during the first read transmission, multiple read transmissions may be performed continuously, and the command cmd may be omitted in the transmission format for the subsequent read transmission(s).

Alternatively, in some embodiments, the random read mode may be initiated by presetting a designated register in the NOR memory (which eliminates the transmission of the read command value at the beginning). That is, the transmission format of the random read mode is represented as:

$$address\_ 1 + \text{......} + address\_n + dummy clk + address\_ 1 \_data + \text{......} + address\_n \_data ,$$

where address_1+ . . . +address_n represent n random access addresses received consecutively, where n is an integer greater than 1; dummy clk represents a predetermined number of dummy clock cycles, where the predetermined number is a number greater than or equal to 0; address_1_data+ . . . +address_n_data represent data read respectively in response to the n random access addresses, which are output consecutively in the order of receiving the access addresses.

In some embodiments, the number of access addresses received consecutively in the random read mode of the present disclosure may be pre-established or determined by the command value (cmd) at the beginning of the transmission or an value of a designated register in the NOR memory.

In some embodiments, the data read from the respective access addresses may be output consecutively in the order of the received access addresses, that is, the order of read data outputted consecutively is consistent with the order of access addresses received consecutively.

In some embodiments, the received access address may be a logical address or a physical address. The access address may include a row address and a column address. In some embodiments, in the case where multiple dies share a common access interface as described later, each access address may also include at least one bit to indicate which die it belongs to. For example, each intra-die access address may further include at least one bit (i.e. a highest bit additionally added) used to indicate die information, so that when decoding the access address, corresponding chip select information may be generated based on the added highest bit information to select the die to which it belongs.

In some embodiments, in the random read mode of the present disclosure, depending on the situation, after all access addresses are successfully received, it is possible to wait for an idle duration before outputting the read data consecutively, or to seamlessly switch to outputting the read data without waiting for any clock cycle. For example, the length of time for reading data for the access address address_1 is less than the length of time for transmitting the access addresses address_2+ . . . +address_n, and then the length of time for the dummy clk is 0 or the transmission format of the random read mode does not include the dummy clk. That is, if the time for transmitting multiple following access addresses in a read transmission is long enough to read the data from the first access address, the dummy clk may be omitted. On the contrary, if the length of time for transmitting multiple subsequent transmission addresses is not long enough to read the data from the first access address, a dummy clk is necessary to ensure sufficient time to read the data from the first access address. For the m^{th} random access address, “multiple subsequent transmission addresses” refers to the (m+1)^{th} to the last (n^{th}) random access addresses in the transmission format. For example, for the first random access address, “multiple subsequent transmission addresses” refers to the second to the last random access addresses in the transmission format.

In some embodiments, the length of the idle time may be preconfigured (the length of idle time is 0 may be considered as no idle time required), or the length of the idle time may be determined by the command value transmitted at the beginning or a value of a designated register, that is set in advance, in the NOR memory.

In some embodiments, the read operation typically adopt a burst mode. For example, after starting a read operation for an access address, a preset burst length of bytes is continuously read, that is, the burst length of bytes are automatically and continuously read starting from the access address. The read operation performed in response to at least one of the received access addresses may be a burst read operation. The burst length for reading each access address or a default burst length may be preconfigured or determined by presetting a value of a specified register in the NOR memory.

In some scenarios, various kinds of the aforementioned designated registers in the NOR memory may be the same set of registers, where values of different bits may be configured to indicate different parameters (such as the mode to be initiated, the number of access addresses consecutively received, the length of idle time, the burst length, etc.); or may be multiple different registers. The host may in advance write various setting values in the corresponding registers at once or write the various setting values in the corresponding registers in batches multiple times as needed before initiating the random read mode.

The technical solution of the present disclosure will be introduced in detail below by taking the NOR memory with SPI interface as an example, but those skilled in the art may understand that the present disclosure is not limited to this, but may also be applied to NOR memories with other serial access interfaces or parallel access interfaces.

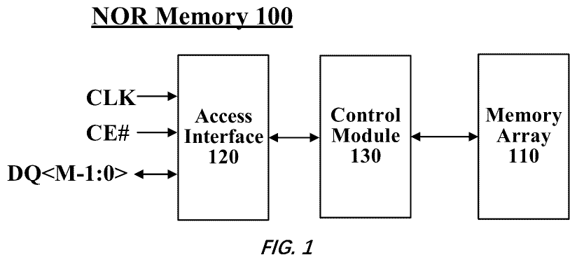

FIG. 1 shows an exemplary composition diagram of a NOR memory according to an embodiment of the present disclosure.

As shown in FIG. 1, the NOR memory 100 includes a memory array 110, an access interface 120 and a control module 130, wherein the access interface 120 is used for communicating information with the outside of the NOR memory, and the control module 130 may be configured to control the read operation of the memory array 110 according to the information received from the access interface 120, so as to implement the novel random read mode proposed in the present disclosure.

In some embodiments, the memory array 110 may include one or more NOR memory arrays.

In some embodiments, the memory array 110 and a part or even the whole of the control module 130 may be fabricated on one die.

In some embodiments, although not shown in FIG. 1, the NOR memory 100 may include more than one dies, each of which is fabricated with one memory array 110. In some embodiments, each die may also include a part or even the whole of the corresponding control module 130. Each memory array 110 on the die may include one or more NOR memory arrays, and the more than one dies share a common access interface 120.

In some embodiments, as shown in FIG. 1, the access interface 120 may use the SPI (Serial Peripheral Interface) protocol to communicate with the external host. The access interface 120 may at least include a clock signal line CLK, a chip enable line CE #, and a set of (M) data/address multiplexing lines DQ<M−1:0>, used for implementing the SPI protocol. When a host performs a read operation on the memory 100, the host may output a clock signal CLK to the memory to control the signal transmission timing (i.e., to enable to perform desired signal transmission at each rising edge and/or falling edge of the CLK), pull down the CE # signal to select the memory, and use the DQ lines to exchange the command, addresses, and/or data related to the read operation with the memory. The SPI protocol in this disclosure may include various versions thereof, such as single-port, dual-port, 4-port, or 8-port SPI protocol. In this disclosure, “single-port”, “dual-port”, “4-port”, or “8-port” refers to the bit width of transmitting data in parallel being 1 bit, 2 bits, 4 bits, or 8 bits, and correspondingly, the SPI protocol for single-port, dual-port, 4-port, or 8-port refers to the number M of data/address multiplexing lines DQ being 1, 2, 4, or 8. The following will describe embodiments of this disclosure using an 8-port SPI (M=8, DQ lines transmit 1 byte in parallel each time, i.e., 8 bits) as an example, but those skilled in the art may understand that the technical solution of this disclosure does not limit the bit number. In addition, in some embodiments, in addition to the data/address multiplexing lines DQ, the access interface 120 may also include other transmission lines to transmit a portion of the data or address separately; for example, the access interface 120 may also include separate address line(s) to transmit the addresses together with and in parallel with the data/address multiplexing lines DQ.

In addition, those skilled in the art may understand that since the present disclosure does not limit the specific implementation of the internal control circuit of the memory used to implement the random read mode proposed in the present disclosure, only a simplified block diagram is used in FIG. 1 to represent the control module 130 in the NOR memory 100. The control module 130 may include various circuit components and their various arrangements involved in performing desired read operations on the memory array 110, for example, may include a command decoder, a row/column decoder, a sense amplifier (SA), a page buffer, and/or various latches or registers (such as an address latch/register, a data latch/register, a configuration register, etc.) as needed.

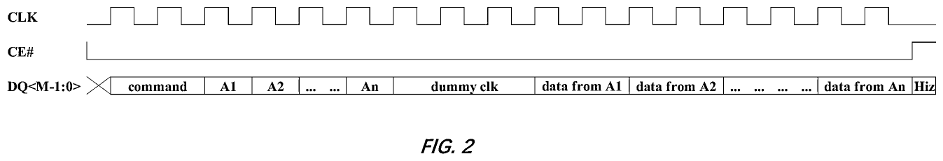

An example of the random read mode of the present disclosure will be described in detail below in conjunction with the timing diagram shown in FIG. 2 and the structural block diagram of FIG. 1. Those skilled in the art may understand that many of the details described below are merely examples for the sake of completeness of the solution and are not intended to limit the technical solution of the present disclosure. For example, although the timing diagram shown in FIG. 2 is implemented using the access interface example of FIG. 1, it may also be adaptively modified to be suitable for NOR memories using other types of serial or parallel access interfaces.

FIG. 2 shows an exemplary timing diagram of a random read mode according to an embodiment of the present disclosure.

As shown in FIG. 2, the host sends the clock signal CLK to the memory, pulls down the chip enable signal CE #, and sends a predetermined command value at the beginning, thereby initiating the random read mode specified by the command value.

In this example, the data transmission on the DQ lines adopts SDR (Single Data Rate) timing, which means that data is transmitted only once per clock cycle. Data with a certain bit width may be transmitted at once at the rising or falling edge of the clock signal CLK. For example, in the case of transmitting data using an SPI interface with a bit width of 8 bits (M=8), one byte of data is transmitted in one clock cycle. Those skilled in the art may understand that the numbers of clock cycles for transmitting each command, address, and read data on the DQ lines shown in FIG. 2 are only exemplary and do not intend to limit the disclosure, and the numbers of clock cycles for transmitting them may be appropriately set according to the interface bit width and the length of each command, address and data during actual application. Those skilled in the art understand that the disclosure is not limited to SDR timing, but may also adopt DDR (Double Data Rate) timing, which means that data can be transmitted at both the rising and falling edges of the CLK, with two data transmissions per clock cycle.

After sending the command value, as shown in FIG. 2, the host consecutively sends n random access addresses A1-An on the DQ lines, where n>1. As mentioned earlier, n may be pre-established or, determined by the command value transmitted at the beginning, or determined by a value of a designated register in the NOR memory. Although the command and the addresses are transmitted seamlessly in FIG. 2, those skilled in the art may understand that the disclosure is not limited to this. For example, in some other embodiments, idle waiting time (dummy clock cycles, i.e., dummy clk) may be inserted between the command and the first address A1 and/or between two consecutive addresses as needed. As shown in FIG. 2, there is a dummy clock cycle (dummy clk) in the timing diagram, but those skilled in the art may understand that there may be no dummy clock cycles (dummy clk) in the timing diagram of FIG. 2.

Then, as shown in FIG. 2, after a predetermined number (which may be 0) of dummy clock cycles (dummy clk), the host starts to receive data from A1 (i.e., data read in bursts from A1); if the burst length is set to 2 bytes, it takes two clock cycles to consecutively transmit 2 bytes of read data. As mentioned earlier, the number of dummy clock cycles and/or the burst lengths for reading the respective access addresses (or the default burst length for all addresses) may be pre-established or determined by the command value transmitted at the beginning or the value of a specified register in the NOR memory. For example, in some cases, there is a read latency (i.e., the time it takes for a complete read operation) from receiving the first address A1 to outputting its corresponding read data, which is mainly affected by the operation time of the SA. Therefore, the number of dummy clock cycles may be calculated based on this read latency and the time required to transmit n access addresses. If n is large enough, after the transmission of the access addresses is completed, the first read operation has also been completed, and data from A1 may be seamlessly output, i.e., the number of dummy clock cycles may be set to 0. That is, the transmission format of the read command may be represented as: cmd+address_1+ . . . +address_n+address_1_data++address_n_data, without the dummy clk. Or, the transmission format of the read command may be represented as: address_1+ . . . +address_n+address_1_data+ . . . +address_n_data, without the dummy clk. If the first read operation has not been completed when the transmission of n access addresses is completed, the number of dummy clock cycles may be set as needed. In this example, in the case of using the SPI serial port, since the transmission directions for the addresses and the read data on the DQ lines are opposite, a transmission direction switching between the last address An and the first read data is necessary. In some cases, this IO switch only takes half of a clock cycle. And due to the SDR timing in the example of FIG. 2, only one data transmission is performed in one clock cycle, so there is an interval of one clock cycle between each two transmissions, which is sufficient for the IO switch without additional dummy clock cycle. The read data means the data read according to the access address.

Then, as shown in FIG. 2, the host seamlessly and consecutively receives data from subsequent access addresses, and then pulls up CE # to terminate this random read mode when it finishes receiving all the data read according to the previously sent access addresses. In the example of FIG. 2, since the memory pre-stores all the access addresses, it may perform read operations on the respective access addresses in a pipeline manner, thereby shortening the interval between consecutive read operations and seamlessly outputting the respective read data. However, this disclosure is not limited to this. In some other embodiments, appropriate dummy clock cycles may be set between consecutive read data as needed. The entire transmission process on the DQ lines shown in FIG. 2 may be preset or pre-agreed by the host, so the host may receive each read data on time and without error according to the presetting/agreement.

In addition, in some other embodiments, if the host does not need the read data from the address received later, the CE # may be pulled up in advance to end the random read mode in advance. For example, the read data that has not been output by the memory when the CE # is pulled up may be discarded, and subsequent read processing may also be stopped completely; or the read operation that is being performed when the CE # is pulled up may be completed before ending the mode. The processing method for the received address and its corresponding read data after the CE # is pulled up may be agreed upon or set in advance. Therefore, the host can flexibly implement any number of consecutive random read operations as needed.

From the above content, it may be concluded that the transmission format of an exemplary read command of the random read mode represented by the timing diagram in FIG. 2 may be expressed as:

$$cmd + address\_ 1 + \text{......} + address\_n + dummy clk + address\_ 1 \_data + \text{......} + address\_n \_data ,$$

where, cmd represents a predetermined command value,
address_1+ . . . +address_n represent n random access addresses received consecutively, where n is an integer greater than 1,
dummy clk represents a predetermined number of dummy clock cycles, where the predetermined number is an integer greater than or equal to 0,
address_1_data+ . . . +address_n_data represent the data read respectively in response to the n random access addresses, which are output consecutively in the order of receiving the access addresses.

In another possible implementation, the random read mode of the present disclosure may be initiated by receiving a predetermined command value cmd, and after initiating to enter the random read mode via the cmd, the predetermined command value cmd may be omitted in the subsequent transmission format. That is, the first transmission format used is: cmd+address_1+ . . . +address_n+dummy clk+address_1_data+ . . . +address_n_data, and in the subsequent transmission, the transmission format used is: address_1+ . . . +address_n+dummy clk+address_1_data+ . . . +address_n_data.

In one possible implementation, the CE # signal may be changed after entering the random read mode, and there is no need to transmit the cmd until the CE # signal is changed (e.g., pulled up).

In addition, as mentioned earlier, in other embodiments, the random read mode may also be initiated by presetting a specific register in the memory, thereby eliminating the transmission of read command value at the beginning of FIG. 2 and further saving transmission time.

In this case, the transmission format of the random read mode may be correspondingly modified as:

$$address\_ 1 + \text{......} + address\_n + dummy clk + address\_ 1 \_data + \text{......} + address\_n \_data ,$$

where, address_1+ . . . +address_n represent n random access addresses received consecutively, where n is an integer greater than 1,
dummy clk represents a predetermined number of dummy clock cycles, where the predetermined number is an integer greater than or equal to 0,
address_1_data+ . . . +address_n_data represent the data read respectively in response to the n random access addresses, which are output consecutively in the order of receiving the access addresses.

In the embodiment of the present disclosure, the random read mode may be initiated by presetting a specific register in the memory, and the same transmission format is also used after initiating the random read mode. That is, the first transmission format used is: address_1+ . . . +address_n+dummy clk+address_1_data+ . . . +address_n_data, and in the subsequent transmission, the transmission format used is: address_1+ . . . +address_n+dummy clk+address_1_data+ . . . +address_n_data.

This variant embodiment may be implemented using various details discussed above or any combination thereof, and will not be further described here.

In the description of the embodiments of the present application, unless otherwise specified, the meaning of “multiple” refers to a quantity of two or more. For example, multiple dies refer to two or more dies. In the embodiments of the present application, “in one possible implementation”, “in some embodiments”, “for example” or similar expressions are used to indicate examples, illustrations, or descriptions. Any embodiment or design scheme described in the embodiments of this application as “in one possible implementation”, “in some embodiments”, or “as an example” should not be interpreted as being more preferred or advantageous than other embodiments or design schemes. Specifically, the use of the expressions like “in one possible implementation”, “in some embodiments”, or “for example” is intended to present relevant concepts in a specific way.

Various embodiments of the present disclosure have been described above, and the foregoing descriptions are exemplary, not exhaustive, and not limiting of the disclosed embodiments. Numerous modifications and variations will be apparent to those of ordinary skill in the art without departing from the scope and spirit of the described embodiments. The terminology used herein was chosen to best explain the principles of the various embodiments, the practical application or improvement over the technology in the marketplace, or to enable others of ordinary skill in the art to understand the various embodiments disclosed herein.

What is claimed is:

1. A method for reading a NOR memory, comprising:
consecutively receiving at least two random access addresses in a random read mode; and
consecutively outputting data read according to the received access addresses.

2. The method according to claim 1, wherein,
the random read mode is initiated by a predetermined command value.

3. The method according to claim 1, wherein,
the random read mode transmission is represented as:
$$cmd + address\_ 1 + \text{......} + address\_n + dummy clk + address\_ 1 \_data + \text{......} + address\_n \_data ,$$
where, cmd represents a predetermined command value,
address_1+ . . . +address_n represent n random access addresses received consecutively, where n is an integer greater than 1,
dummy clk represents a number of dummy clock cycles, where the number is a number greater than or equal to 0,
address_1_data+ . . . +address_n_data represent data read respectively in response to the n random access addresses, which are output consecutively in the order of the received access addresses.

4. The method according to claim 1, wherein the random read mode is initiated by value of a designated register in the NOR memory.

5. The method according to claim 4, wherein,
the random read mode transmission is represented as:
$$address\_ 1 + \text{......} + address\_n + dummy clk + address\_ 1 \_data + \text{......} + address\_n \_data ,$$
where, address_1+ . . . +address_n represent n random access addresses received consecutively, where n is an integer greater than 1,
dummy clk represents a predetermined number of dummy clock cycles, where the predetermined number is a number greater than or equal to 0,
address_1_data+ . . . +address_n_data represent data read respectively according to the n random access addresses, which are output consecutively in the order of the access addresses received.

6. The method according to claim 2, wherein the random read mode is a continuous read mode which includes at least two continuous read transmissions, wherein each read transmission comprises at least two random access addresses received consecutively and data outputted consecutively; wherein the data is read according to the corresponding received access addresses.

7. The method according to claim 6, wherein,
the first read transmission of the continuous read transmissions is:
$$cmd + address\_ 1 + \text{......} + address\_n + dummy clk + address\_ 1 \_data + \text{......} + address\_n \_data ;$$
and
the following read transmission of the continuous read transmissions is:
$$address\_ 1 + \text{......} + address\_n + dummy clk + address\_ 1 \_data + \text{......} + address\_n \_data ,$$
where, address_1+ . . . +address_n represent n random access addresses received consecutively, where n is an integer greater than 1,
dummy clk represents a predetermined number of dummy clock cycles, where the predetermined number is a number greater than or equal to 0,
address_1_data+ . . . +address_n_data represent data read respectively according to the n random access addresses, which are output consecutively in the order of the received access addresses.

8. The method according to claim 3, wherein,
the number of n or the number of dummy clock cycles is predetermined, or determined according to the command value or a value of a designated register, that is set in advance, in the NOR memory.

9. The method according to claim 1, wherein,
the read operation performed in response to receiving the at least one of access addresses is a burst read operation,
the burst length for each access address or a default burst length is predetermined, or determined by a value of a designated register, that is set in advance, in the NOR memory.

10. The method according to claim 1, wherein,
at least two of the received access addresses include at least two access addresses belonging to different dies, and each of the access addresses includes at least one bit of information indicating the die the access address belongs to.

11. The method according to claim 1, wherein,
the NOR memory has an access interface using a SPI protocol; and/or
the NOR memory has a single-port, dual-port, four-port or eight-port access interface; and/or
the NOR memory adopts SDR timing to receive the access addresses and output the read data.

12. The method according to claim 3, wherein the length of time for reading data according to the access address address_1 is less than the length of time for transmitting the access addresses address_2+ . . . +address_n, and the length of time for the dummy clk is 0 or the transmission format of the random read mode does not include the dummy clk.

13. The method according to claim 1, wherein, the random read mode comprises:
a parameter indicating the random read mode is initiated,
n random access addresses received consecutively, where n is an integer greater than 1,
a dummy clk indicating a number of dummy clock cycles, where the number is a number greater than or equal to 0,
output data read respectively according to the n random access addresses, which are output consecutively in the order of the received access addresses.

14. The method according to claim 1, wherein the random read mode is a continuous read mode which includes at least two continuous read transmissions,
wherein each read transmission includes at least two random access addresses received consecutively and data outputted consecutively;
wherein the data is read according to the corresponding received access addresses.

15. The method according to claim 1, wherein the random read mode is a continuous read mode which includes at least two continuous read transmissions,
wherein the first read transmission comprises:
a parameter indicating the random read mode is initiated,
n random access addresses received consecutively, where n is an integer greater than 1,
a dummy clk indicating a number of dummy clock cycles, where the number is a number greater than or equal to 0; and
output data read respectively according to the n random access addresses, which are output consecutively in the order of the received access addresses;
wherein the second read transmission comprises:
n random access addresses received consecutively, where n is an integer greater than 1,
a dummy clk indicating a number of dummy clock cycles, where the number is a number greater than or equal to 0; and
output data read respectively according to the n random access addresses, which are output consecutively in the order of the received access addresses.

16. A NOR memory comprising:
one or more NOR memory arrays fabricated on one or more dies;
an access interface for communicating information with the outside of the NOR memory; and
a control module configured to control a read operation to the NOR memory arrays according to information received from the access interface, so as to implement the method according to claim 1.
